(19) United States
(12) Patent Application Publication
(10) Pub. No.: US 2025/0112182 A1
(43) Pub. Date: Apr. 3, 2025

(54) SEMICONDUCTOR PACKAGE WITH AN INSULATION LAYER

(71) Applicant: TEXAS INSTRUMENTS INCORPORATED, DALLAS, TX (US)

(72) Inventors: Masamitsu Matsuura, BEPPU-SHI OITA-KEN (JP); Daiki Komatsu, BEPPU-SHI OITA-KEN (JP); Kengo Aoya, BEPPU-SHI OITA-KEN (JP); Ting-Ta Yen, San Jose, CA (US)

(21) Appl. No.: 18/478,226

(22) Filed: Sep. 29, 2023

(51) Int. Cl. H01L 23/00; H01L 21/56; H01L 23/31

(52) U.S. Cl. CPC H01L 24/05; H01L 21/561; H01L 23/3107; H01L 24/03; H01L 24/48; H01L 24/85; H01L 2224/0361; H01L 2224/04042; H01L 2224/05111; H01L 2224/05139; H01L 2224/05556; H01L 2224/05647; H01L 2224/48245; H01L 2224/85

(57) ABSTRACT

A semiconductor package includes a semiconductor wafer having a first connection pad and a second connection pad spaced apart by a semiconductor region of the semiconductor wafer. Portions of the semiconductor wafer are covered by a protective overcoat. The semiconductor package also includes a cap wafer mounted to the semiconductor wafer and overpassing the semiconductor region of the semiconductor wafer. The cap wafer extends between the first connection pad and the second connection pad of the semiconductor wafer. The semiconductor package further includes an insulation material overlaying the cap wafer. The insulation material comprising vias to the first connection pad and the second connection pad, the vias being filled with a conductive material.

### TECHNICAL FIELD

This description relates to semiconductor packages with an insulation layer.

### BACKGROUND

In some semiconductor packages, vias are used to allow current to pass from a via from one semiconductor component to another within an integrated electronic device. During the formation vias, various conductive layers or films are typically deposited on a semiconductor wafer by a process, such as electroplating. For example, copper is often used to form a via because of copper's relatively high electrical conductivity. Metals of high electrical conductivity, however, resist adhering to other layers formed on the semiconductor wafer. Poor adhesion of layers within a via results in delamination at the interfaces due to thermal stress and electromigration of the conductive material as ions which make up the lattice of the conductive material move along an electric field through the weak interface.

### SUMMARY

A first example is related to a semiconductor package. The semiconductor package includes a semiconductor wafer having a first connection pad and a second connection pad spaced apart by a semiconductor region of the semiconductor wafer. Portions of the semiconductor wafer are covered by a protective overcoat. The semiconductor package also includes a cap wafer mounted to the semiconductor wafer and overpassing the semiconductor region of the semiconductor wafer. The cap wafer extends between the first connection pad and the second connection pad of the semiconductor wafer. The semiconductor package further includes an insulation material overlaying the cap wafer. The insulation material includes vias to the first connection pad and the second connection pad, the vias being filled with a conductive material.

A second example is related to a method for forming semiconductor packages. The method includes mounting a cap wafer on a semiconductor wafer to form stacked wafers. The semiconductor wafer includes an array of dies. The dies include a first connection pad and a second connection pad that are spaced apart by a semiconductor region of a respective die of the dies. The method also includes etching the cap wafer to expose the first connection pad and the second connection pad of the dies, such that a portion of the cap wafer overpasses the semiconductor region of the dies. The method further includes coating the cap wafer with an insulation material. The method yet further includes processing the insulation material to form vias in the insulation material to the first connection pad and the second connection pad of the dies. The method additionally includes depositing a conductive material in the vias and singulating the stacked wafers.

### BRIEF DESCRIPTION OF THE DRAWINGS

FIG. 1 illustrates an example of a stacked wafer semiconductor ready for packaging.

FIG. 2 illustrates an example of a wafer chip scale package.

FIG. 3 illustrates an example of a flat no-leads configuration of a semiconductor package.

FIG. 4 illustrates an example of a first stage of a first method for forming the stacked wafer semiconductor.

FIG. 5 illustrates an example of a second stage of the first method for forming the stacked wafer semiconductor.

FIG. 6 illustrates an example of a third stage of the first method for forming the stacked wafer semiconductor.

FIG. 7 illustrates an example of a fourth stage of the first method for forming the stacked wafer semiconductor.

FIG. 8 illustrates an example of a fifth stage of the first method for forming the stacked wafer semiconductor.

FIG. 9 illustrates an example of a sixth stage of the first method for forming the stacked wafer semiconductor.

FIG. 10 illustrates an example of a seventh stage of the first method for forming the stacked wafer semiconductor.

FIG. 11 illustrates an example of a first stage of a second method for forming the semiconductor package.

FIG. 12 illustrates an example of a second stage of the second method for forming the semiconductor package.

FIG. 13 illustrates an example of a first stage of a third method for forming the semiconductor package.

FIG. 14 illustrates an example of a second stage of the third method for forming the semiconductor package.

FIG. 15 illustrates an example of a third stage of the third method for forming the semiconductor package.

FIG. 16 illustrates a flowchart of an example method for fabricating a stacked wafer semiconductor with an insulation layer.

### DETAILED DESCRIPTION

Semiconductor packages include multiple semiconductor components. The semiconductor components are in electrical communication through vias so that current passes from one semiconductor component to another semiconductor component. As one example, a via (e.g., trench) is etched into a layer of silicon wafer or other dielectric that separates the semiconductor components. The via includes conductive material to allow current to pass from one semiconductor component to another in the semiconductor package. The conductive layers are formed of a conductive material, such as copper, palladium, gold, silver, or other appropriate conductive metal or metal alloy with similar properties.

The conductive layers are deposited on a semiconductor wafer by a process of electroplating. In some examples, the conductive layers are separated from the semiconductor components by depositing various intermediary layers on the semiconductor wafer. In one example, an insulation layer is first deposited on the semiconductor wafer by plasma-enhanced chemical vapor deposition (PE-CVD). The insulation layer material includes silicon dioxide that electrically isolates between silicon cap wafer and subsequently deposited layers on the semiconductor wafer.

After deposition of the insulation layer, the bottom of insulation layer is etched to open the connection pad area, then a seed layer is deposited on the semiconductor wafer. The seed layer is formed of a conductive material (e.g., titanium, copper). Because of the use of wafer bonding material (e.g., SU-8) between silicon cap wafer and device wafer, in conventional approaches, the seed layer covers the side wall of silicon cap and the wafer bonding material. However, the bonding material deforms due to pressure during wafer to wafer bonding and the resulting deformed shape yields poor coverage of the seed layer.

In the semiconductor packages and methods described herein, an insulation layer overlays the cap wafer and forms the sidewalls of the vias that are filled with a conductive material. Instead of the insulation material employed in conventional approaches, the insulation layer is deposited and the vias are etched to connection pads in the semiconductor wafer. The insulation layer acts as a buffer layer and reduces the risk of cracking due to stress and reduces the number of photolithography steps during fabrication. In some examples, the vias in the insulation layer are tapered with a wider opening at an end of the via distal from the corresponding connection pad. The tapered sidewalls increase coverage of the seed layer and/or the conductive material during deposition. In various examples, the insulation layer includes a photosensitive material and/or a non-photosensitive material. In one example, the photosensitive material is patterned by photolithography processes. The non-photosensitive material is patterned by laser ablation.

FIG. 1 illustrates an example of a stacked wafer semiconductor 100 ready for packaging. The stacked wafer semiconductor 100 includes a semiconductor circuit module 102. In some examples, the semiconductor circuit module 102 is integrated with a semiconductor wafer 104 and includes a semiconductor region 106. The semiconductor wafer 104 is a substrate, such as silicon, silicon carbide, or other suitable material, either in substantially pure form or in combination with additional materials. As another example, the semiconductor wafer 104 is a single crystal material, such as a single crystal silicon substrate.

The formation of the semiconductor wafer 104 is dependent on the application of the semiconductor circuit module 102. As one example, the semiconductor wafer 104 is a complementary metal-oxide semiconductor (CMOS) substrate and includes circuitry formed thereon. The circuitry in the semiconductor wafer 104 is coupled to the semiconductor circuit module 102 and performs a suitable function (e.g., controlling operation of a mechanical resonator, detecting vibration of the mechanical resonator, etc.) for the application. In one example, the semiconductor circuit module 102 of the semiconductor wafer 104 comprises a resonator, such as an LC resonator, microelectromechanical systems (MEMS) resonator, surface acoustic wave (SAW) resonator, a bulk acoustic wave (BAW) resonator, or other external resonator. In some such examples, the stacked wafer semiconductor 100 is a stress sensor and the semiconductor circuit module 102 is a field-effect transistor having a structure for detecting a stress generated therein. In yet another example, the semiconductor wafer 104 does not have circuitry formed thereon.

A protective overcoat 108 overlays (e.g. covers) the semiconductor wafer 104. A wafer bond layer 110 overlays the protective overcoat 108. The wafer bond layer 110 is formed of a non-conductive material such as epoxy or other suitable non-conductive material (e.g., SU-8). The stacked wafer semiconductor 100 also includes a cap wafer 112. In one example, the semiconductor region 106 forms a cavity and the cap wafer 112 facilitates formation of a hermetic seal (e.g., a vacuum seal) of the cavity. In another example, the cap wafer 112 is a CMOS cap with the integrated circuitry formed thereon.

Vias 114 provide an electrical connection to the semiconductor circuit module 102 through connection pads, such as a first connection pad 116 and a second connection pad 118. The first connection pad 116 and the second connection pad 118 are spaced apart by the semiconductor region 106 in a longitudinal direction. The cap wafer 112 is mounted to the semiconductor wafer 104 and overpasses the semiconductor region 106 of the semiconductor wafer 104.

The vias 114 include a conductive material 120. The conductive material 120 is copper, or other conductive material. Electrical signals are communicated with the semiconductor circuit module 102 through the vias 114 enabling electrical communication. In the example stacked wafer semiconductor 100, the vias 114 are separated by the semiconductor circuit module 102. While two vias 114 are shown in other examples, there are fewer or a greater number of vias 114.

An insulation material 122 overlays the cap wafer 112 and forms sidewalls of the vias 114. The sidewalls of a corresponding via include a first sidewall 124 opposite a second sidewall 126 in a longitudinal direction. The first sidewall 124 is separated from the second sidewall 126 by the conductive material 120. In some examples, a seed layer separates the conductive material 120 and the insulation material 122. A body portion 128 of the insulation material 122 is approximately parallel to the semiconductor wafer 104. The body portion 128 has a first side 130 and a second side 132 that extend in a longitudinal direction. The first side 130 forms a top surface of the stacked wafer semiconductor 100. The second side 132 of the body portion 128 is adjacent the cap wafer 112.

The insulation material 122 is patterned. In one example, the insulation material 122 changes in solubility in response to irradiation such that the insulation material 122 is capable of being patterned with light. In another example, the insulation material is patterned with an ablation laser. The insulation material 122 is polyimide (PI), polybenzoxazole (PBO), SU-8, Ajinomoto Build-up Film (ABF) or other suitable material with similar properties. The insulation material 122 forms a nonconductive insulation layer. The insulation material 122 operates as a buffer layer and reduces the risk of cracking due to stress and reduces the number of photolithography steps during fabrication. More particularly, the conductive material 120, the protective overcoat 108, the wafer bond layer 110, and the cap wafer 112 have different moduli of Young's modulus. Moreover, the insulation material 122 has a lower Young's modulus than the conducive material 120 and the protective overcoat 108. Thus, the insulation material 122 operates as the buffer layer (alternatively referred to as a shock absorber) to accommodate the differential expansion or contraction between the conducive material 120 and the protective overcoat 108, the wafer bond layer 110, and the cap wafer 112. In some examples, the vias 114 in the insulation material 122 are tapered with a wider opening at an end of the via 114 distal from the corresponding connection pad 116, 118.

The sidewalls 124, 126 extend from the body portion 128 and separate the conductive material 120 from the protective overcoat 108, the wafer bond layer 110, and the cap wafer 112. Due to being patterned with light or ablation laser, the sidewalls 124, 126 of the insulation material 122 have a regular even surface. The sidewalls 124, 126 have a smoother surface than the wafer bond layer 110 after being etched.

A depth of the vias 114 is defined in the lateral direction orthogonal to the longitudinal direction. The conductive material 120 extends from a first surface 134 of the first connection pad 116 and the second connection pad 118. The conductive material 120 extends to the first side 130 of the body portion 128 from the first surface 134. In some examples, the depth of vias 114 extends beyond the first side 130 of the body portion 128 in the lateral direction.

The sidewalls 124, 126 of the insulation material 122 are tapered such that the vias 114 have a wider opening at an end distal from the corresponding connection pads 116, 118. Widths of the vias 114, defined in a longitudinal direction, are based on the separation between the opposing sidewalls 124, 126 of the vias 114. In some examples, the widths of the vias 114 include a first width at a first depth continuous with the first surface 134 and a second width continuous with a surface of the first side 130 of the body portion 128. Accordingly, the first width is proximal the connection pads 116, 118, and the second width is distal the connection pads 116, 118. The second width is greater than the first width. In one example, the first width is at least five micrometers and the second width is dependent on the depth of the vias 114 in the lateral direction. As one example, the vias 114 have a truncated cone shape.

The taper of the sidewalls 124, 126 forms an angle 136 relative to the first surface 134 of the connection pads 116, 118. The angle 136 is less than 90 degrees. In some examples, the angle 136 is between 30 degrees and 89 degrees. The regular even surface of the sidewalls 124, 126 conforms to the angle. The taper improves coverage of materials deposited in the vias 114, such as a seed layer or the conductive material 120.

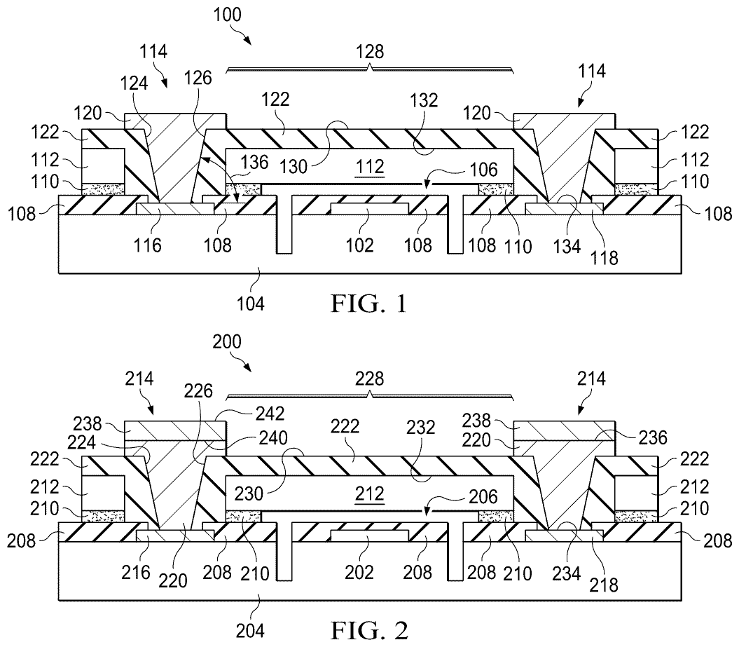

FIG. 2 illustrates an example of a wafer chip scale package (WCSP) configuration 200 of a semiconductor package including the stacked wafer semiconductor 100 of FIG. 1. WCSP configuration 200 includes a semiconductor circuit module 202. In some examples, the semiconductor circuit module 202 is integrated with a semiconductor wafer 204 and includes a semiconductor region 206. The protective overcoat 208 overlays (e.g., covers) the semiconductor wafer 204. A wafer bond layer 210 overlays the protective overcoat 208. A cap wafer 212 overlays the wafer bond layer 210.

Vias 214 (e.g., the vias 114 of FIG. 1) provide an electrical connection to the semiconductor circuit module 202 through connection pads, such as a first connection pad 216 and a second connection pad 218. The vias 214 are filled with a conductive material 220 such as copper. An insulation material 222 (e.g., the insulation material 122 of FIG. 1) overlays the cap wafer 212. The insulation material 222 forms sidewalls including a first sidewall 224 and a second sidewall 226 of the vias 214. The sidewalls 224, 226 extend from a body portion 228 and separate the conductive material 220 from the protective overcoat 208, the wafer bond layer 210, and the cap wafer 212. The body portion 228 has a first side 230 and a second side 232 opposite the first side 230 that extend in a longitudinal direction. The depth of the conductive material 120 of the vias 214 extends beyond the first side 230 of the body portion 228 in the lateral direction away from the semiconductor wafer 204. For example, the depth of the conductive material 120 extends from a first surface 234 of the connection pads 216, 218 to a conductive surface 236.

Widths of the vias 214, defined in a longitudinal direction, are based on the separation between the opposing sidewalls of the vias 214. In some examples, the widths of the vias 214 include a first width at a first depth defined by the first surface 234 and a second width defined by a surface of the first side 230. Accordingly, the first width is proximal the connection pads 216, 218, and the second width is distal the connection pads 216, 218. The second width is greater than the first width.

The ends of the vias 214 are defined by a conductive surface 236 of the conductive material 220 of the vias 214. The vias 214 are coated with solderable metal layer 238. The solderable metal layer 238 provides a protective coating that prevents oxidation at the conductive surface 236 of the conductive material 220. The solderable metal layer 238 is formed of a solderable metal material. Examples of the solderable metal material include various forms of nickel, palladium, silver, tin, gold, etc. In one example, the conductive material 220 is copper (Cu) and the solderable metal layer 238 is tin/silver alloy. Accordingly, the solderable metal layer 238 provides electrical plating on ends of the copper in the vias 214.

The solderable metal layer 238 is formed by applying the solderable metal material to the conductive surface 236 of the conductive material 220 in a deposition process, such as electroplating. The solderable metal layer 238 has a first plating surface 240 and a second plating surface 242 opposite the first plating surface 240 extending in the longitudinal direction. The first plating surface 240 is adjacent the conductive surface 236 of the conductive material 220. The solderable metal layer 238 has a width bounded by the width of the conductive material 220 in the longitudinal direction. The second plating surface 242 forms a top surface of the flip chip configuration 200 of a semiconductor package.

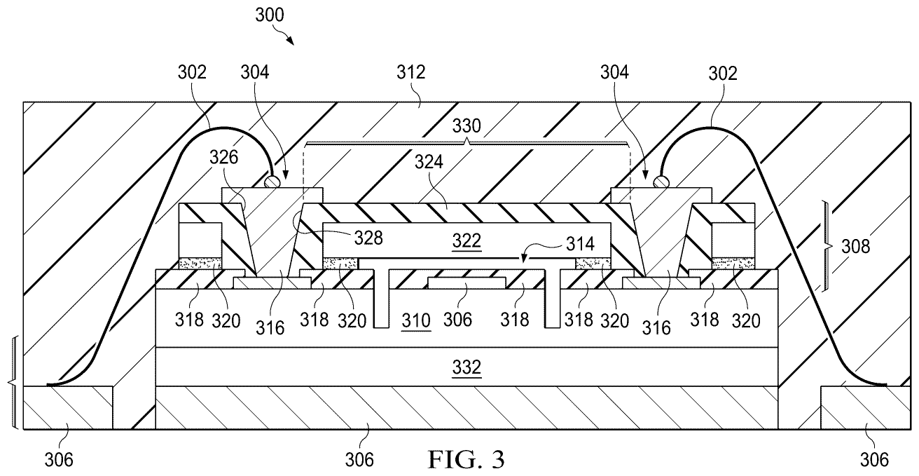

FIG. 3 illustrates an example of a flat no-leads configuration 300 of the semiconductor package including the stacked wafer semiconductor 100 of FIG. 1 with a wire bonds 302, such as a quad flat no-leads (QFN) configuration or a dual flat no-leads (DFN) configuration. The wire bonds 302 forms an electrical connection between vias 304 (e.g., the vias 114 of FIG. 1, the vias 214 of FIG. 2) and an interconnect 306. The interconnect 306 is separated from the semiconductor wafer by a die attach material 332. A semiconductor circuit module 308 is mounted on the semiconductor wafer 310 encapsulated in a molding 312 on a top side of the semiconductor circuit module 308. The vias 304 are separated by a semiconductor region 314 and are filled with a conductive material 316.

A protective overcoat 318 overlays the semiconductor wafer 310. A wafer bond layer 320 overlays the protective overcoat 318. A cap wafer 322 overlays the wafer bond layer 320. An insulation material 324 (e.g., insulation material 122 of FIG. 1, insulation material 222 of FIG. 2) overlays the cap wafer 322 and forms the sidewalls of the vias 304. The sidewalls include a first sidewall 326 and a second sidewall 328 extending from a body portion 330 and are separated by the conductive material 316 of the respective via 304. The sidewalls 326, 328 are tapered with a wider opening at an end distal from the corresponding connection pad.

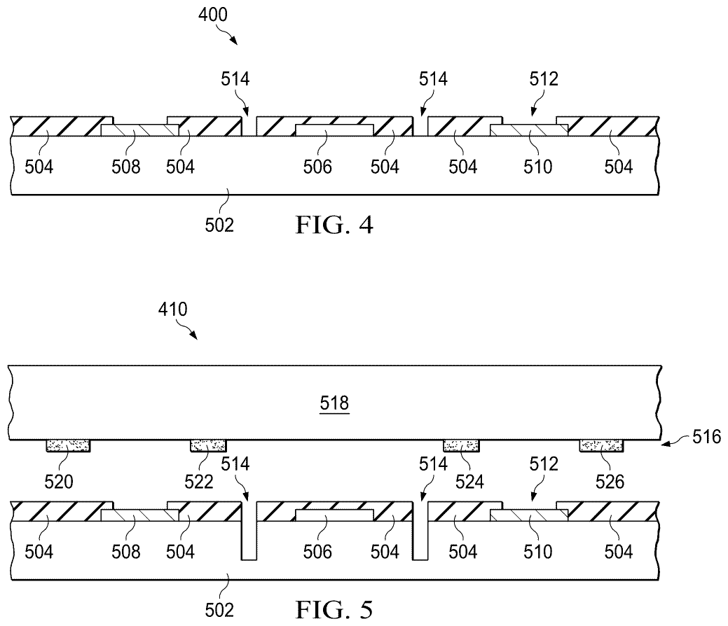

FIGS. 4-10 illustrate stages of a method for formation of the stacked wafer semiconductor, such as the stacked wafer semiconductor 100 of FIG. 1 with an insulation layer. For purposes of simplification, FIGS. 4-10 employ the same reference numbers to denote the same structure.

FIG. 4 illustrates an example of a first stage 400 of a first method of forming the stacked wafer semiconductor 100. A semiconductor wafer 502 is provided and a protective overcoat 504 is deposited over the semiconductor wafer 502. Circuitry is integrated over the semiconductor wafer 502 within the protective overcoat 504. For example, conductive elements including a semiconductor circuit module 506, a first connection pad 508, and a second connection pad 510 are integrated within the protective overcoat 504. The conductive elements are formed of a conductive material.

The protective overcoat 504 is removed from over portions of the first connection pad 508 and the second connection pad 510 forming etched regions 512 that expose the connection pads 508, 510. The protective overcoat 504 is further deposited and/or etched to form trenches 514 separated by the semiconductor circuit module 506. Accordingly, the protective overcoat 504 is discontinuous in the longitudinal direction and has a variable height in the lateral direction depending on the position of the etched regions 512.

FIG. 5 illustrates an example of a second stage 410 of the first method for forming the stacked wafer semiconductor. In the second stage 410, a wafer bond layer 516 is coated on a cap wafer 518. The wafer bond layer 516 is discontinuous in the longitudinal direction and is formed of a number of sections including a first section 520, a second section 522, a third section 524, and a fourth section 526.

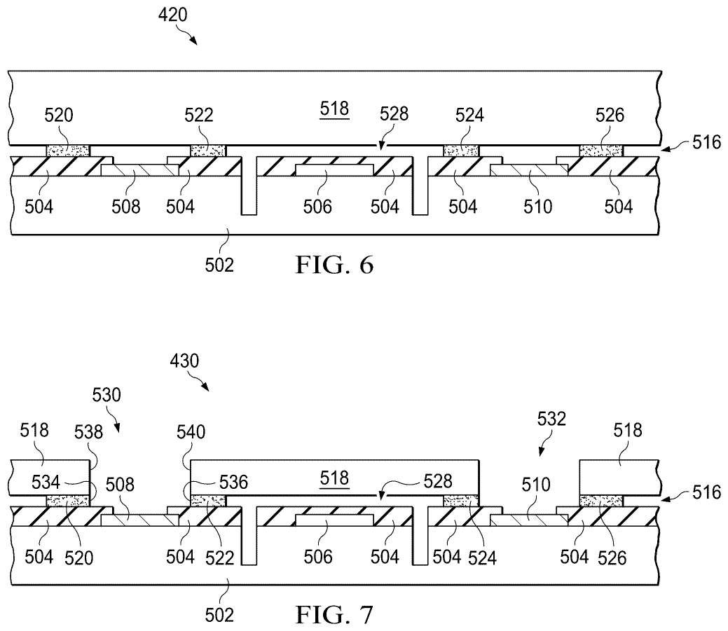

FIG. 6 illustrates an example of a third stage 420 of the first method for forming the stacked wafer semiconductor. In the third stage 420, the cap wafer 518 is bonded to the protective overcoat 504 by virtue of the wafer bond layer 516. Responsive to the bonding, the first section 520 and the second section 522 of the wafer bond layer 516 are separated by the first connection pad 508 in the longitudinal direction such that the first section 520 is distal the semiconductor circuit module 506 and the second section 522 is proximal the semiconductor circuit module 506. Likewise, responsive to the bonding, the third section 524 and the fourth section 526 of the wafer bond layer 516 are separated by the second connection pad 510 in the longitudinal direction such that the third section 524 is proximal the semiconductor circuit module 506 and the fourth section 526 is distal the semiconductor circuit module 506.

When bonded, a semiconductor region 528 is defined by the second section 522 and the third section 524 of the wafer bond layer 516. In one example, the semiconductor region 528 is a cavity having a width from an edge, extending in the lateral direction and proximal the semiconductor circuit module 506, of the second section 522 to an edge, extending in the lateral direction and proximal the semiconductor circuit module 506, of the third section 524. The cavity has a top surface defined by the cap wafer 518 and a bottom surface, opposite the top surface, defined by the protective overcoat 504 on the semiconductor wafer 502. The bottom surface is also defined by the bottom of the trenches 514. In some examples, the cavity of the semiconductor region 528 is sealed and creates an inert or non-inert environment, such as a vacuum environment for a mechanical resonator and for the semiconductor circuit module 506, such as an electrode.

FIG. 7 illustrates an example of a fourth stage 430 of the first method for forming the stacked wafer semiconductor. In the fourth stage 430, the cap wafer 518 is etched over the first connection pad 508 and the second connection pad 510 such that the cap wafer 518 is discontinuous in the longitudinal direction. By virtue of the etching, a first opening 530 is formed over the first connection pad 508 and a second opening 532 is formed over the second connection pad 510. The openings 530, 532 have sidewalls formed by the cap wafer 518 and the sections of the wafer bond layer 516 that extend in the lateral direction and are approximately orthogonal to a surface of the connection pads 508, 510 extending in a longitudinal direction.

As one example, the cap wafer 518 is etched to form sidewalls continuous with the orthogonal sidewalls of the sections of the wafer bond layer 516. In such an example, the first section 520 of the wafer bond layer 516 has a first wafer bond sidewall 534 that extends in the lateral direction from a surface of the protective overcoat 504 to the cap wafer 518. The second section 522 of the wafer bond layer 516 has a second wafer bond sidewall 536 that opposes the first wafer bond sidewall 534. The second wafer bond sidewall 536 extends in the lateral direction from the surface of the protective overcoat 504 to the cap wafer 518. The first wafer bond sidewall 534 and the second wafer bond sidewall 536 are orthogonal to a surface of the protective overcoat 504 extending in the longitudinal direction.

In the fourth stage, the cap wafer 518 is etched so that the sidewalls of the first opening 530 have a first opening sidewall 538 and a second opening sidewall 540 opposite the first opening sidewall 538. The first opening sidewall 538 includes the first wafer bond sidewall 534 and continues the plane of the first wafer bond sidewall 534 through the cap wafer 518. The second opening sidewall 540 includes the second wafer bond sidewall 536 and continues the plane of the second wafer bond sidewall 536 through the cap wafer 518.

As another example, the wafer bond layer 516 and the cap wafer 518 are both etched to define the first opening sidewall 538 and the second opening sidewall 540 as planar surfaces. The planar surfaces of the first opening sidewall 538 and the second opening sidewall 540 define edges of the wafer bond layer 516 and the cap wafer 518. The second opening 532 is formed over the second connection pad 510 in a similar manner as described with respect to the first opening 530. For example, the opening sidewalls of the second opening 532 are etched to define planar surfaces through the wafer bond layer 516 and the cap wafer 518 that are orthogonal to a plane defined by the semiconductor wafer 502.

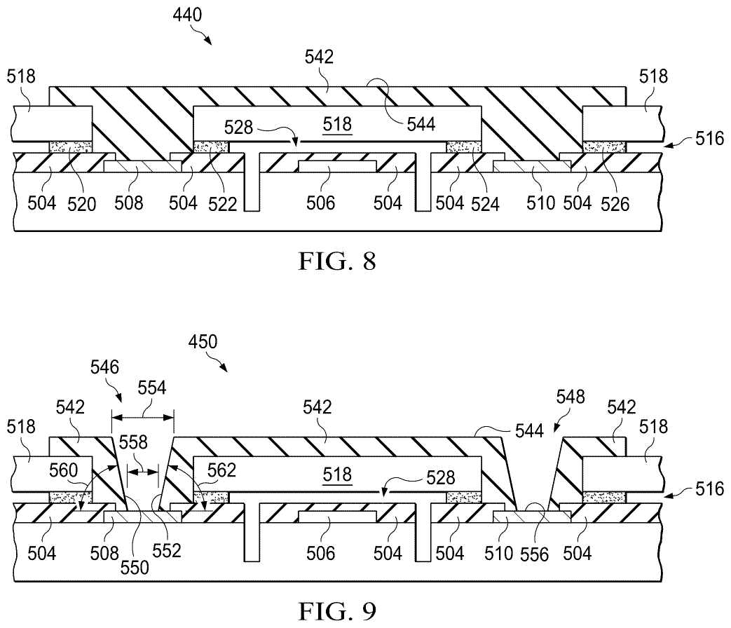

FIG. 8 illustrates an example of a fifth stage 440 of the first method for forming the stacked wafer semiconductor. In the fifth stage 440, an insulation material 542 (e.g., insulation material 122 of FIG. 1, insulation material 222 of FIG. 2, insulation material 324 of FIG. 3) is deposited over the cap wafer 518 and into the first opening 530 and the second opening 532 to form an approximately planar surface 544 of the insulation material 542. The insulation material 542 is deposited using a spin coating operation or a splay coating operation or a lamination operation to achieve the planar surface 544 of the insulation material 542. In one example, the insulation material 542 is deposited by submerging the structure shown in FIG. 7 in the insulation material 542 or solution thereof as a pre-dipping operation. The pre-dipping operation allows the insulation material 542 or solution thereof to fill the first opening 530 and the second opening 532 in situations where the first opening 530 and the second opening 532 have a high aspect ratio. The pre-dipping operation is followed by a spin coating operation to remove excess insulation material from the insulation material 542 or the solution thereof.

FIG. 9 illustrates an example of a sixth stage 450 of the first method for forming the stacked wafer semiconductor. In the sixth stage 450, the insulation material 542 is patterned to form a first cavity 546 to the first connection pad 508 and a second cavity 548 to the second connection pad 510. The first cavity 546 and the second cavity 548 extend in an orthogonal direction from the planar surface 544 of the insulation material 542 to the first connection pad 508 and the second connection pad 510, respectively.

The first cavity 546 and the second cavity 548 are defined in the longitudinal direction by via sidewalls of the insulation material 542. For example, the first cavity 546 is defined by a first via sidewall 550 and a second via sidewall 552. The distance between opposing sidewalls of a cavity characterizes the width of the resulting via. For example, the width of the first cavity 546 is defined by the first via sidewall 550 and the second via sidewall 552. In some examples, the sidewalls of the first cavity 546 and the second cavity 548 are tapered such that the width of the first cavity 546 and the second cavity 548 are different. For example, the first cavity 546 has a first width 554 at an end defined by the planar surface 544, distal from a connection pad surface 556 of the first connection pad 508 and the second connection pad 510. The first width 554 is larger than a second width 558 proximal the connection pad surface 556. Accordingly, the opposing sidewalls of the cavities, and resulting vias, are separated by a shorter distance at the connection pad surface 556 than at the planar surface 544.

The opposing sidewalls of the first cavity 546 and the second cavity 548 are tapered. For example, the first via sidewall 550 forms a first angle 560 with the connection pad surface 556 and the second via sidewall 552 forms a second angle 562 with the connection pad surface 556. The first angle 560 and the second angle 562 may be the same or different. The first angle 560 and/or the second angle 562 are angles between 30 degrees and 89 degrees.

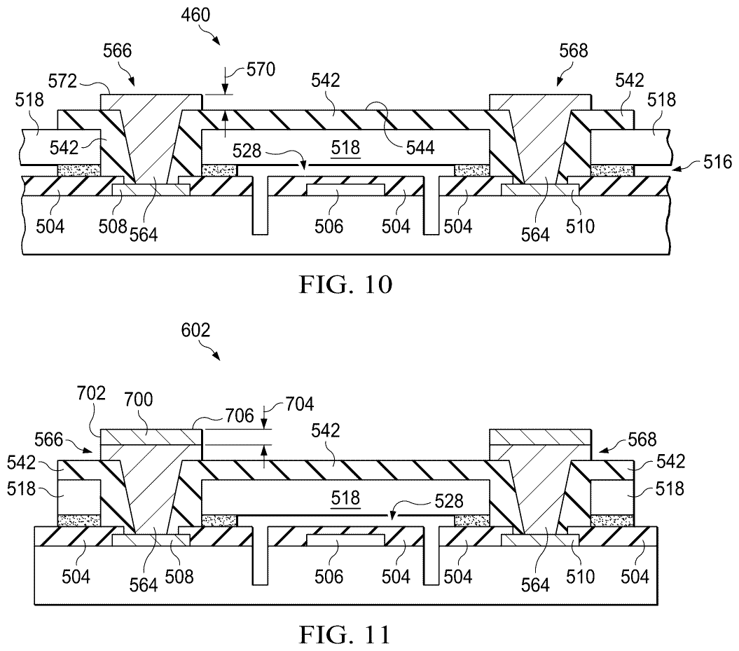

FIG. 10 illustrates an example of a seventh stage 460 of the first method for forming the stacked wafer semiconductor. In the seventh stage 460, the first cavity 546 and the second cavity 548 are filled with a conductive material 564 to form a first via 566 (e.g., vias 114 of FIG. 1, vias 214 of FIG. 2, vias 304 of FIG. 3) and a second via 568 (e.g., vias 114 of FIG. 1, vias 214 of FIG. 2, vias 304 of FIG. 3). The conductive material 564 is copper. The conductive material 564 is deposited and etched to extend beyond the planar surface 544 of the insulation material 542 at a conductive height 570 to form a conductive surface 572.

FIG. 11 illustrates an example of a first stage 602 of a second method for forming a semiconductor package including a stacked wafer semiconductor, such as the stacked wafer semiconductor 100 of FIG. 1, with a flip-chip configuration. The stages 400-460 of the first method of semiconductor fabrication are performed before the first stage 602 of the second method. The second method is executed in response to execution of the first method, described above with respect to FIG. 4-10, to fabricate the semiconductor package in a flip chip configuration.

In the first stage 602, the conductive surface 572 is coated with solderable metal layer 700 that extends from the conductive height 570 in the lateral direction forming solderable metal sidewall 702 having a solderable metal height 704. The solderable metal layer 700 has a solderable metal surface 706 opposite the from the planar surface 544 of the insulation material 542 and separated from the planar surface 544 by the solderable metal height 704.

The solderable metal layer 700 provides a protective coating that prevents oxidation at the conductive material 564 at the conductive surface 572. The solderable metal layer 700 is formed of a solderable metal material. Examples of the solderable metal material include various forms of nickel, palladium, tin, silver, gold, etc. In the illustrated example, the conductive material 564, here copper (Cu), and the solderable metal layer 700 is formed of a solderable material, such as matted tin (Sn), tin silver, or other appropriate solderable material with similar properties. The solderable metal layer 700 is formed by applying the solderable metal material to the conductive surface 572 in a deposition process, such as electroplating. The solderable metal layer 700 is bounded in the longitudinal direction by the insulation material 542.

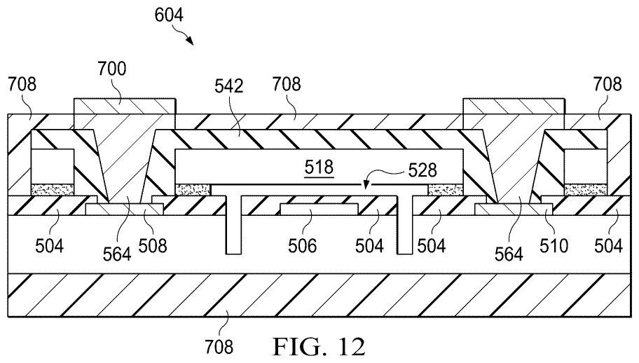

FIG. 12 illustrates an example of a second stage 604 of the second method for forming the semiconductor package. The stacked wafer semiconductor shown in the first stage 602 is encapsulated in molding 708 to protect the semiconductor package in the flip chip configuration. For example, the molding 708 encapsulates the semiconductor wafer 502, the cap wafer 518, and the insulation material 542. In some examples, such as a wafer chip scale package configuration, the molding 708 is omitted.

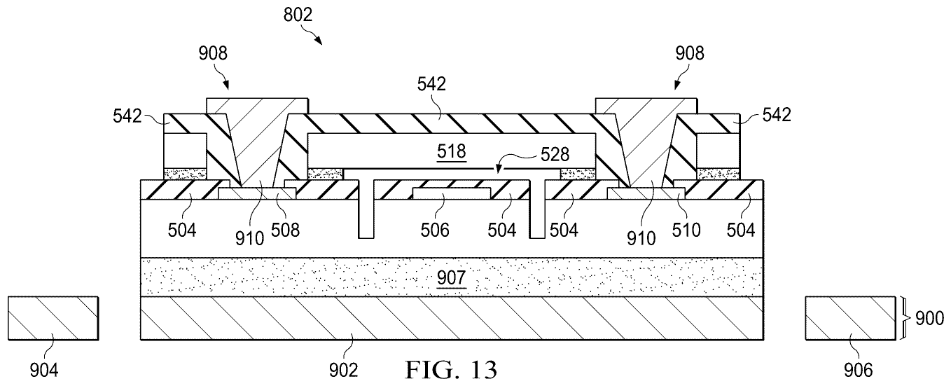

FIG. 13 illustrates an example of a first stage 802 of a third method for forming the semiconductor package including a stacked wafer semiconductor, such as the stacked wafer semiconductor 100 of FIG. 1, with a flat no-leads configuration. The stages 400-460 of the first method of semiconductor fabrication are executed in response to execution of the first stage 802 of the third method. The third method is performed after the first method, described above with respect to FIGS. 4-10, to fabricate the semiconductor package in a flat no leads configuration.

In the first stage 802, the stacked wafer semiconductor shown in FIG. 10 is mounted on an interconnect 900 (alternatively referred to as a leadframe). In particular, the interconnect 900 includes a wafer pad 902, a first lead 904, and a second lead 906. The stacked wafer semiconductor shown in FIG. 10 is mounted to the wafer pad 902 with a die attach material 907. The first lead 904 and the second lead 906 are exposed to an external environment to enable device(s) of the stacked wafer semiconductor to be electrically coupled with one or more other electrical components external to the stacked wafer semiconductor.

The stacked wafer semiconductor includes vias 908 (e.g., vias 114 of FIG. 1, vias 214 of FIG. 2, vias 304 of FIG. 3, vias 566, 568 of FIG. 10). The vias 908 include a conductive material 910, such as copper. The vias 908 provide an electrically conductive path through the stacked wafer semiconductor to corresponding connection pads 912.

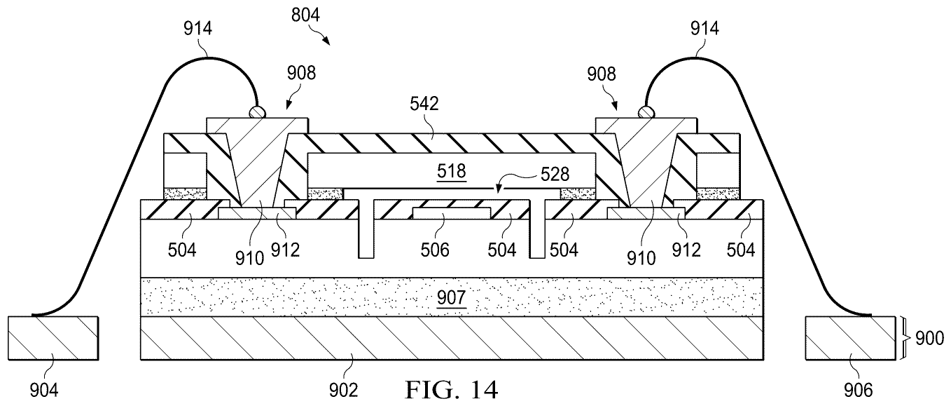

FIG. 14 illustrates an example of a second stage 804 of the third method for forming the semiconductor package. The second stage 804 includes applying wire bonds 914 between ends of the copper deposited in the vias 908 and leads 904, 906 of the interconnect 900. Wire bonds 914 are formed from the conductive material 910 of the vias 908 or other conductive material. Accordingly, the wire bonds 914 form a conductive pathway from the connection pads 912 to the interconnect 900.

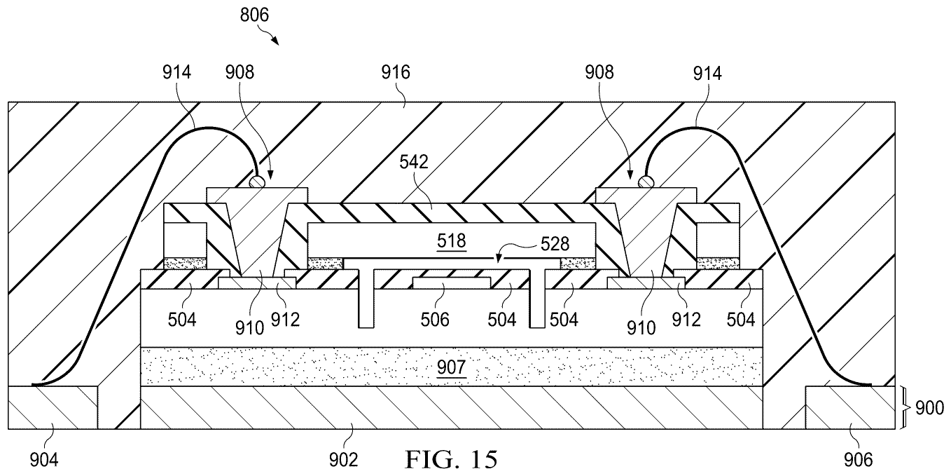

FIG. 15 illustrates an example of a third stage 806 of the third method for forming the semiconductor package. In the third stage 806, the stacked wafer semiconductor shown in the second stage 804 is encapsulated in molding 916 to protect the semiconductor package in the flat no leads configuration.

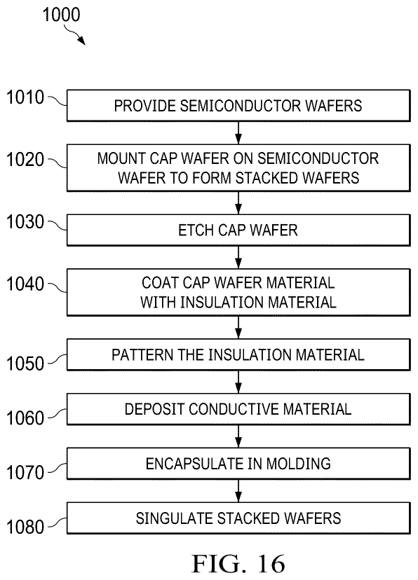

FIG. 16 illustrates an example process flow 1000 for fabricating a stacked wafer semiconductor, such as the stacked wafer semiconductor 100 of FIG. 1 with a insulation layer. At 1010, a semiconductor wafer (e.g., semiconductor wafer 104 of FIG. 1, semiconductor wafer 204 of FIG. 2, semiconductor wafer 310 of FIG. 3, semiconductor wafer 502 of FIG. 4) is provided. In some examples, the semiconductor wafer is mounted on an interconnect. The semiconductor wafer includes an array of dies. The dies include a corresponding first connection pad (e.g., the first connection pad 116 of FIG. 1) and a corresponding second connection pad (e.g., the second connection pad 118 of FIG. 1) that are spaced apart by a semiconductor region, of the semiconductor regions, by a respective die of the dies.

At 1020 a cap wafer (e.g., cap wafer 112 of FIG. 1, cap wafer 212 of FIG. 2, cap wafer 322 of FIG. 3, cap wafer 518 of FIG. 5) is mounted on the semiconductor wafer to form stacked wafers. At 1030, the cap wafer is etched to expose the first connection pad and the second connection pad of the dies, such that a portion of the cap wafer overpasses the semiconductor region of the dies.

At 1040, the cap wafer is coated with an insulation material (e.g., insulation material 122 of FIG. 1, insulation material 222 of FIG. 2, insulation material 324 of FIG. 3, insulation material 542 of FIG. 8). The insulation material is polyimide or PBO. In one example, the coating includes spray coating the insulation material on the cap wafer. In another example, the coating includes spin coating the insulation material on the cap wafer. In another example, the coating includes lamination of the insulation material on the cap wafer. In some examples, the coating includes spin coating the insulation material on the cap wafer material.

At 1050, the insulation material is patterned to form vias in the insulation material to the first connection pad and the second connection pad of the dies. In one example, the insulation material on the cap wafer material is tapered with a wider opening at an end distal from the corresponding connection pad. The taper of the vias has an angle between 30 degrees and 89 degrees.

At 1060, a conductive material is deposited in the vias. In one example, the conductive material is copper. The conductive material is deposited using electrical plating with seed layer or metal printing. At 1070 the semiconductor package is encapsulated in molding. At 1080, the stacked wafers are singulated. Singulation separates the semiconductor packages in the array. In one example, singulation cuts a molding and an interconnect associated with the leads resulting in singulated semiconductor packages. In one example, the semiconductor regions of the corresponding semiconductor packages include resonators.

In this description, unless otherwise stated, “about,” “approximately” or “substantially” preceding a parameter means being within +/−10 percent of that parameter. Modifications are possible in the described embodiments, and other embodiments are possible, within the scope of the claims.

What is claimed is:

1. A semiconductor package comprising:
a semiconductor wafer having a first connection pad and a second connection pad spaced apart by a semiconductor region of the semiconductor wafer, wherein portions of the semiconductor wafer are covered by a protective overcoat;
a cap wafer mounted to the semiconductor wafer and overpassing the semiconductor region of the semiconductor wafer, wherein the cap wafer extends between the first connection pad and the second connection pad of the semiconductor wafer; and
a insulation material overlaying the cap wafer, the insulation material comprising vias to the first connection pad and the second connection pad, the vias being filled with a conductive material.

2. The semiconductor package of claim 1, wherein the vias of the insulation material are tapered with a wider opening at an end distal from the first connection pad and the second connection pad.

3. The semiconductor package of claim 2, further comprising a molding encapsulating the semiconductor wafer, the cap wafer and the insulation material.

4. The semiconductor package of claim 3, wherein the conductive material filling the vias is copper.

5. The semiconductor package of claim 4, further comprising matted tin or tin silver plating on ends the copper in the vias.

6. The semiconductor package of claim 4, further comprising wire bonding between ends of the copper in the vias and leads of an interconnect.

7. The semiconductor package of claim 3, wherein the semiconductor region of the semiconductor wafer comprises resonator.

8. The semiconductor package of claim 7, wherein the semiconductor package is a stress sensor.

9. The semiconductor package of claim 2, wherein the taper of the vias has an angle between 30 degrees and 89 degrees.

10. The semiconductor package of claim 1, wherein the insulation material is polyimide, PBO or SU-8.

11. A method for forming semiconductor packages, the method comprising:
mounting a cap wafer on a semiconductor wafer to form stacked wafers, wherein the semiconductor wafer includes an array of dies, the dies including a first connection pad and a second connection pad that are spaced apart by a semiconductor region of a respective die of the dies;
etching the cap wafer to expose the first connection pad and the second connection pad of the dies, such that a portion of the cap wafer overpasses the semiconductor region of the dies;
coating the cap wafer with a insulation material;
processing the insulation material to form vias in the insulation material to the first connection pad and the second connection pad of the dies;
depositing a conductive material in the vias; and
singulating the stacked wafers.

12. The method of claim 11, wherein the vias of the insulation material are tapered with a wider opening at an end distal from the first connection pad and the second connection pad.

13. The method of claim 12, wherein the conductive material deposited in the vias is copper.

14. The method of claim 13, further comprising:
plating matted tin or tin silver plating on ends of the copper deposited in the vias; and
encapsulating the stacked wafers in a molding.

15. The method of claim 13, further comprising:
mounting the stacked wafers on an interconnect;
applying wire bonds between ends of the copper deposited in the vias and leads of the interconnect; and
encapsulating the stacked wafers in a molding.

16. The method of claim 13, wherein the taper of the vias has an angle between 30 degrees and 89 degrees.

17. The method of claim 11, wherein the semiconductor regions of the semiconductor wafer comprises resonators.

18. The method of claim 11, wherein the coating comprises spray coating the insulation material on the cap wafer.

19. The method of claim 11, wherein the coating comprises spin coating the insulation material on the cap wafer.

20. The method of claim 11, wherein the coating comprises lamination of the insulation material on the cap wafer.
